(19) United States
(12) Patent Application Publication
(10) Pub. No.: US 2013/0167633 A1
(43) Pub. Date: Jul. 4, 2013

(54) INERTIAL SENSOR AND METHOD OF MANUFACTURING THE SAME

(71) Applicants: Seng Mo LIM, Suwon (KR); Sung Jun LEE, Goyang-si (KR); Sang Jin KIM, Suwon (KR); Jung Won LEE, Seoul (KR); Yun Sung KANG, Suwon (KR); Kyo Yeol LEE, Yongin-si (KR)

(72) Inventors: Seng Mo LIM, Suwon (KR); Sung Jun LEE, Goyang-si (KR); Sang Jin KIM, Suwon (KR); Jung Won LEE, Seoul (KR); Yun Sung KANG, Suwon (KR); Kyo Yeol LEE, Yongin-si (KR)

(73) Assignee: SAMSUNG ELECTRO-MECHANICS CO., LTD., Gyunggi-do (KR)

(21) Appl. No.: 13/408,932

(22) Filed: Feb. 29, 2012

(30) Foreign Application Priority Data
Dec. 30, 2011 (KR) 1020110146800

(51) Int. Cl. G01C 19/56; H01L 41/22

(52) U.S. Cl. 73/504.12; 29/25.35

(57) ABSTRACT

Disclosed herein are an inertial sensor and a method of manufacturing the same. The inertial sensor 100 according to a preferred embodiment of the present invention includes a membrane 110, a piezoelectric body 120 formed in a multilayer above the membrane 110, a first electrode 130 formed between the membrane 110 and the piezoelectric body 120, a second electrode 140 formed on an exposed surface of the piezoelectric body 120, and a third electrode 150 formed between layers of the piezoelectric body 120 formed in a multilayer.

### CROSS REFERENCE TO RELATED APPLICATION

This application claims the benefit of Korean Patent Application No. 10-2011-0146800, filed on Dec. 30, 2011, entitled “Inertial Sensor and Method of Manufacturing the Same”, which is hereby incorporated by reference in its entirety into this application.

### BACKGROUND OF THE INVENTION

1. Technical Field

The present invention relates to an inertial sensor and a method of manufacturing the same.

2. Description of the Related Art

Recently, an inertial sensor has been used as various applications, for example, military such as an artificial satellite, a missile, an unmanned aircraft, or the like, vehicles such as an air bag, electronic stability control (ESC), a black box for a vehicle, or the like, hand shaking prevention of a camcorder, motion sensing of a mobile phone or a game machine, navigation, or the like.

The inertial sensor generally adopts a configuration in which a mass body is adhered to an elastic substrate such as a membrane, or the like, in order to measure acceleration and angular velocity. Through the configuration, the inertial sensor may calculate the acceleration by measuring inertial force applied to the mass body and may calculate the angular velocity by measuring Coriolis force applied to the mass body.

In detail, a scheme of measuring the acceleration and the angular velocity using the inertial sensor is as follows. First, the acceleration may be calculated by Newton's law of motion “F=ma”, where “F” represents inertial force applied to the mass body, “m” represents a mass of the mass body, and “a” is acceleration to be measured. Among others, the acceleration a may be obtained by sensing the inertial force F applied to the mass body and dividing the sensed inertial force F by the mass m of the mass body that is a predetermined value. Further, the angular velocity may be calculated by Coriolis force “F=2 mΩ×v”, where “F” represents the Coriolis force applied to the mass body, “m” represents the mass of the mass body, “Ω” represents the angular velocity to be measured, and “v” represents the motion velocity of the mass body. Among others, since the motion velocity V of the mass body and the mass m of the mass body are values known in advance, the angular velocity Ω may be calculated by detecting the Coriolis force F applied to the mass body.

Meanwhile, the inertial sensor according to the prior art includes a piezoelectric body that is formed above a membrane (diagram) so as to drive a mass body or sense the displacement of the mass body, as disclosed in Korean Laid-Open Patent No. 10-2011-0072229. However, the piezoelectric disposed above the membrane is a single layer and therefore, force driving the mass body may be relatively weak when voltage is applied thereto. Further, when the displacement of the mass body is sensed, the relatively lower voltage is output. As a result, sensitivity of the inertial sensor may be degraded.

### SUMMARY OF THE INVENTION

The present invention has been made in an effort to provide an inertial sensor and a method of manufacturing the same capable of driving a mass body even though relatively lower voltage is applied to a piezoelectric body and outputting relatively higher voltage when a displacement of the mass body is sensed, by forming the piezoelectric body in a multilayer.

According to a preferred embodiment of the present invention, there is provided an inertial sensor, including: a membrane; a piezoelectric body formed in a multilayer above the membrane; a first electrode formed between the membrane and the piezoelectric body; a second electrode formed on an exposed surface of the piezoelectric body; and a third electrode formed between layers of the piezoelectric body formed in a multilayer.

The third electrode may include first pads.

The first pads may be exposed from the piezoelectric body and the second electrode.

The inertial sensor may further include: a via connecting the first electrode with the second electrode by penetrating through the piezoelectric body and a second pat connected with the via.

The first electrode may be a common electrode formed over the membrane and the second electrode may be a common electrode formed over the piezoelectric body.

The first electrode and the second electrode may be grounded.

The third electrode may be patterned.

The third electrode may include: driving electrodes; sensing electrodes; wirings connected with the driving electrodes and the sensing electrodes; and first pads connected with ends of the wirings.

The inertial sensor may further include a surface treatment layer formed on the first pads.

The inertial sensor may further include: a mass body disposed under a central portion of the membrane; and posts disposed under edges of the membrane.

According to another preferred embodiment of the present invention, there is provided a method of manufacturing an inertial sensor, including: (A) forming a first electrode on a membrane; (B) forming a piezoelectric body on the first electrode in a multilayer and forming a third electrode between layers of the piezoelectric body formed in a multilayer; and (C) forming a second electrode on an exposed surface of the piezoelectric body.

At step (B), the third electrode may further include first pads.

The method may further include exposing the first pads by selectively removing the piezoelectric body and the second electrode after step (C).

The method may further include forming a via connecting the first electrode with the second electrode by penetrating through the piezoelectric body and second pads connected with the via.

At step (A), the first electrode may be a common electrode formed over the membrane and at step (C), the second electrode may be a common electrode formed over the piezoelectric body.

At step (B), the third electrode may be patterned.

The third electrode may include: driving electrodes; sensing electrodes; wirings connected with the driving electrodes and the sensing electrodes; and first pads connected with ends of the wirings.

At step (B), a passivation layer may be formed so as to protect the first pads after the third electrode is formed and the passivation layer may be removed after step (C).

The method may further include forming a surface treatment layer on the first pads after step (C).

The inertial sensor further include: a mass body disposed under a central portion of the membrane; and posts disposed under edges of the membrane.

### BRIEF DESCRIPTION OF THE DRAWINGS

FIG. 1 is a diagram schematically showing an inertial sensor according to a preferred embodiment of the present invention;

FIG. 2A is a plan view of the inertial sensor according to the preferred embodiment of the present invention;

FIG. 2B is a cross-sectional view taken along line A-A′ of FIG. 2A;

FIG. 2C is a cross-sectional view taken along line B-B′ of FIG. 2A;

FIG. 3 is a cross-sectional view showing a modified example of the inertial sensor shown in FIG. 2B;

FIG. 4 is a plan view showing a third electrode of the inertial sensor shown in FIG. 2;

FIGS. 5 to 14 are cross-sectional views and plan views showing a process sequence of a method of manufacturing an inertial sensor according to a preferred embodiment of the present invention; and

FIGS. 15 to 23 are cross-sectional views and plan views showing a process sequence of a method of manufacturing an inertial sensor according to another preferred embodiment of the present invention.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In the description, the terms “first”, “second”, and so on are used to distinguish one element from another element, and the elements are not defined by the above terms. Further, in describing the present invention, a detailed description of related known functions or configurations will be omitted so as not to obscure the subject of the present invention.

Hereinafter, preferred embodiments of the present invention will be described in detail with reference to the accompanying drawings.

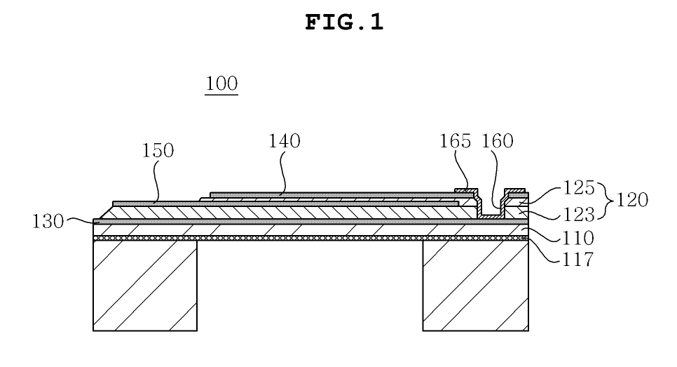

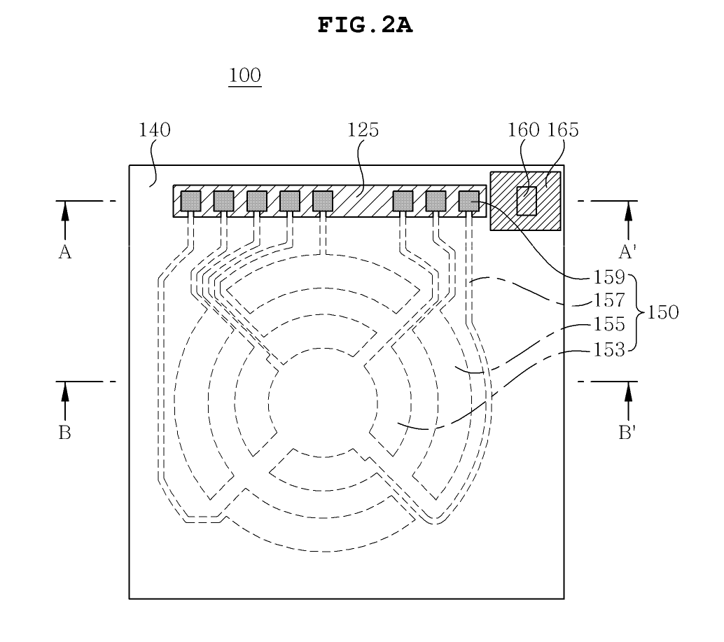

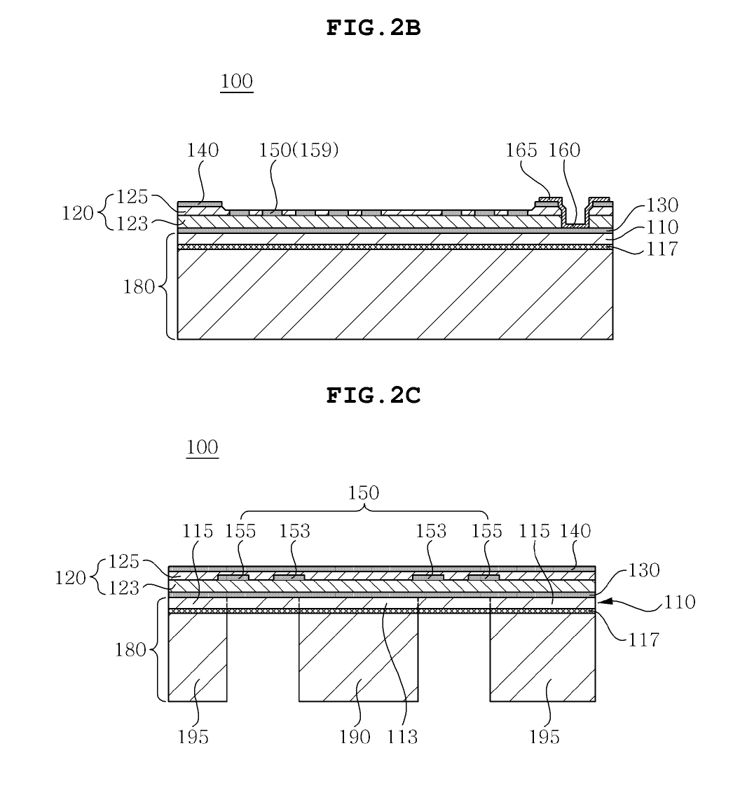

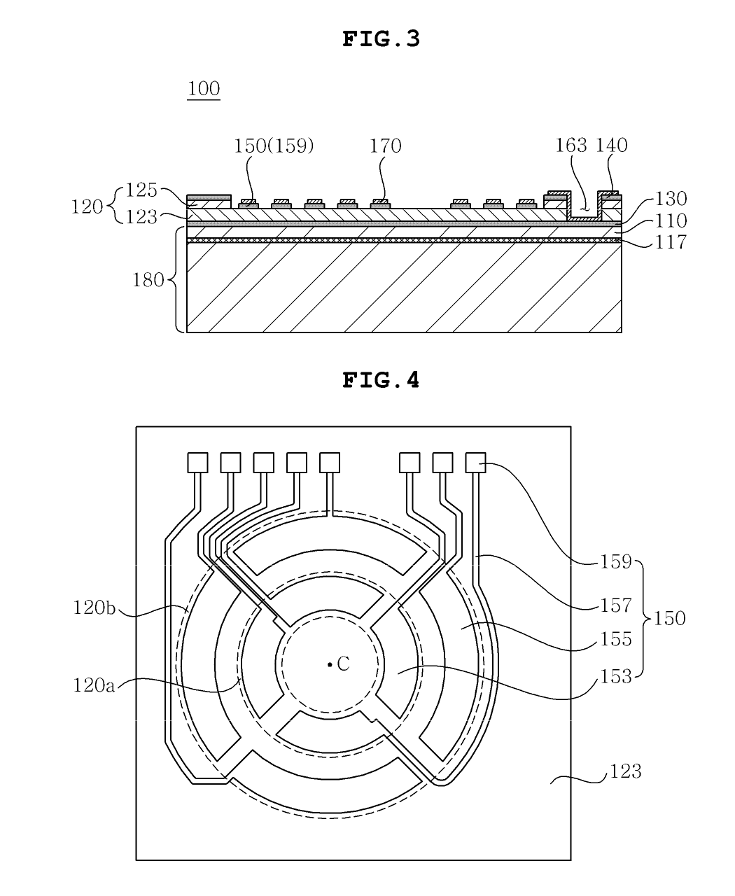

FIG. 1 is a diagram schematically showing an inertial sensor according to a preferred embodiment of the present invention, FIG. 2A is a plan view of the inertial sensor according to the preferred embodiment of the present invention, FIG. 2B is a cross-sectional view taken along line A-A′ of FIG. 2A, FIG. 2C is a cross-sectional view taken along line B-B′ of FIG. 2A, and FIG. 3 is a cross-sectional view showing a modified example of the inertial sensor shown in FIG. 2B.

As shown in FIGS. 1 to 3, an inertial sensor 100 according to a preferred embodiment of the present includes a membrane 110, a piezoelectric body 120 formed in a multilayer above the membrane 110, a first electrode 130 formed between the membrane 110 and the piezoelectric body 120, a second electrode 140 formed on an exposed surface of the piezoelectric body 120, and a third electrode 150 formed between the layers of the piezoelectric body 120 formed in a multilayer.

The membrane 110 is formed in a plate shape and has elasticity so as to displace a mass body 190. In this configuration, a boundary of the membrane 110 is not accurately identified. As shown FIG. 2C, the membrane 110 may be partitioned into a central portion 113 of the membrane 110 and an edge 115 disposed along an outside of the membrane 110. In this case, the mass body 190 is disposed under the central portion 113 of the membrane 110 and posts 195 are disposed under the edges 115 of the membrane 110. Therefore, the edges 115 of the membrane 110 are fixed by being supported to the posts 195 and the displacement corresponding to a movement of the mass body 190 is generated at the central portion 113 of the membrane 110 based on the edges 115 of the fixed membrane 110.

Describing in more detail the mass body 190 and the posts 195, the mass body 190 is disposed under the central portion 113 of the membrane 110 and is displaced by inertial force or Coriolis force. In addition, the posts 195 are formed in a hollow shape to support the bottom portion of the edge 115 of the membrane 110, such that the posts 195 serves to secure a space in which the mass body 190 may be displaced. In this case, the mass body 190 may be formed in, for example, a cylindrical shape and the posts 195 may be formed in a rectangular pillar shape having a cavity in a cylindrical shape formed at a center thereof. That is, when being viewed from a transverse section, the mass body 190 is formed in a circular shape and the posts 195 are formed in a rectangular shape having a circular opening provided at the center thereof. However, the shape of the mass body 190 and the posts 195 is not limited thereto and thus, the mass body 190 and the posts 195 may be formed in all the shapes that are known to those skilled in the art.

Meanwhile, the above-mentioned membrane 110, mass body 190, and posts 195 may be formed by selectively etching a silicon on insulator (SOI) substrate to which a micro electromechanical systems (MEMS) process is easily applied. Therefore, a silicon oxide film (SiO₂) 117 of the SOI substrate may remain between the mass body 190 and the membrane 110 and between the posts 195 and the membrane 110. However, the membrane 110, the mass body 190, and the posts 195 do not need to be formed by etching the SOI substrate but may be formed by etching a general silicon substrate, or the like.

The piezoelectric body 120 and the first, second, and third electrodes 130, 140, and 150 serve to drive the mass body 190 or sense the displacement of the mass body 190. Here, the piezoelectric body 120 is formed above the membrane 110 in a multilayer of two or more layers. For example, the piezoelectric body 120 may be formed in two layers, including a first piezoelectric body 123 and a second piezoelectric body 125. Further, the piezoelectric body 120 may be made of lead zirconate titanate (PZT), barium titanate (BaTiO₃), lead titanate (PbTiO₃), lithium niobate (LiNbO₃), silicon dioxide (SiO₂), or the like. Meanwhile, the first electrode 120 is formed between the membrane 110 and the piezoelectric body 120, the second electrode 140 is formed on the exposed surface of the piezoelectric body 120, and the third electrode 150 of at least one layer is formed between the layers of the piezoelectric body 120 formed in a multilayer. Therefore, when voltage is applied to the piezoelectric body 120 through the first electrode 130, the second electrode 140, and the third electrode 150, an inverse piezoelectric effect that expands and contracts the piezoelectric body 120 is generated. The mass body 190 formed under the membrane 110 may be driven using the inverse piezoelectric effect. On the other hand, when stress is applied to the piezoelectric body 120, a piezoelectric effect of applying voltage to the first electrode 130, the second electrode 140, and the third electrode 150 is generated. The displacement of the mass body 190 disposed on under the membrane 110 may be sensed by using the piezoelectric effect. In detail, the first electrode 130 is a common electrode formed over the membrane 110, the second electrode 140 is the common electrode formed over the piezoelectric body 120, and the first electrode 130 and the second electrode 140 may be connected to each other by a via 160 penetrating through the piezoelectric body 120 (see FIG. 2B). In addition, the third electrode 150 may be patterned to include driving electrodes 153, sensing electrodes 155, wirings 157, and first pads 159 (see FIG. 2A). Therefore, after the first electrode 130 and the second electrode 140 that are the common electrode are grounded, the mass body 190 may be driven when voltage is applied to the driving electrodes 153 of the third electrode 150 and when the mass body 190 is displaced, voltage may be generated in the sensing electrodes 155 of the third electrode 150 to sense the displacement of the mass body 190.

FIG. 4 is a plan view showing a third electrode of the inertial sensor shown in FIG. 2. Referring to FIG. 4, the third electrode 150 will be described in more detail.

The third electrode 150 is patterned and may include, for example, four driving electrodes 153 and four sensing electrodes 155. Here, the four driving electrodes 153 serve to drive the mass body 190 by using the reverse piezoelectric effect and the four sensing electrodes 155 serve to sense the displacement of the mass body 190 by using the piezoelectric effect. In this case, the driving electrodes 153 and the sensing electrodes 155 may each be formed in an arc. For example, when the piezoelectric body 120 is partitioned into an inner annular region 120a surrounding a predetermined point C and an outer annular region 120b surrounding the inner annular region 120a, the inner annular region 120a may be patterned with the driving electrodes 153 in an arch divided into N (N is a natural number, four in the drawings) and the outer annular region 120b may be patterned with the sensing electrodes 155 in an arc divided into M (M is a natural number, four in the drawings).

However, the position of the driving electrodes 153 and the sensing electrodes 155 may be changed from each other. For example, the driving electrodes 153 may be formed in the outer annular region 120b and the sensing electrodes 155 may be formed in the inner annular region 120a. In addition, when the inertial sensor 100 is used as an acceleration sensor, there is no need to drive the mass body 190 and therefore, the driving electrodes 153 may be omitted.

Meanwhile, the third electrode 150 may include the wirings 157 connected with the driving electrodes 153 and the sensing electrodes 155, and the first pads 159 connected with ends of the wirings 157. Here, the wirings 157 electrically connect the driving electrodes 153 and the sensing electrodes 155 with the first pads 159, wherein the first pads 159 is connected with a control unit such as an integrated circuit, or the like, by wire bonding, or the like. In this case, the first pads 159 are connected with the integrated circuit and therefore, the first pads 159 need to be exposed from the piezoelectric body 120 and the second electrode 140 (see FIG. 2A or 2B). In addition, as shown in FIG. 3, the exposed first pads 159 is provided with a surface treatment layer 170 made of gold (Au), or the like, thereby preventing the first pads 159 from being oxidized and ensuring the high electric conductivity.

In addition, in order to connect the first electrode 130 and the second electrode 140 with the control unit, a second pad 165 connected with a via 160 may be provided (see FIG. 2B). Here, the second pad 165 extends from the via 160 so as to be formed on the second electrode 140 and finally, the second pads 165 is connected with the control unit such as the integrated circuit, or the like, by the wire bonding, or the like.

Consequently, the control unit is connected in an order of second pad 165→first and second electrodes 130 and 140 and is connected in an order of first pads→wiring 157→driving electrode 153 or sensing electrode 155 to drive the mass body 190, thereby sensing the displacement of the mass body 190.

The inertial sensor 100 according to the preferred embodiment of the present invention may drive the mass body 190 like the prior art even though the relatively lower voltage is applied, by forming the piezoelectric body 120 in a multilayer. In addition, when the same voltage as the prior art is applied, the mass body 190 may be largely driven. In detail, according to Equation “h∝(E/t)”, the displacement h of the piezoelectric body 120 is in proportion to applied voltage E and is in inverse proportion to a thickness t of the piezoelectric body 120. Therefore, when the piezoelectric body 120 is laminated in two layers by thinly forming the thickness t of the piezoelectric body 120 to ½, the displacement h of the piezoelectric body 120 is implemented like the prior art due to the thickness t thinned to ½ even though only ½ of the existing voltage E is applied. In addition, according to the above Equation, after the piezoelectric body 120 is laminated in two layers by thinly forming the thickness t of the piezoelectric body 120 to ½, the displacement h of the piezoelectric body 120 is increased twice due to the thickness t thinned to ½ when the same voltage E as the prior art is applied.

In addition, the inertial sensor 100 according to the preferred embodiment of the present invention outputs the relatively higher voltage when the displacement of the mass body 190 is sensed by forming the piezoelectric body 120 in a multilayer, thereby increasing the sensitivity of the inertial sensor 100. In detail, according to the equation “h∝(E/t)”, the voltage E output between the first electrode 130 and the third electrode 150 or between the second electrode 140 and the third electrode 150 is in proportion to the displacement h of the piezoelectric body 120 and is in inverse proportion to the thickness t of the piezoelectric body 120. Therefore, when the piezoelectric body 120 is laminated in two layers by thinly forming the thickness t of the piezoelectric to ½, the output voltage E is increased twice due to the thickness t thinned to ½ even though the same displacement h as the prior art is generated.

Meanwhile, the inertial sensor 100 according to the preferred embodiment of the present invention may thinly implement the thickness of the piezoelectric body 120 while forming the piezoelectric body 120 in a multilayer. As described above, when the thickness of the piezoelectric body 120 is thinly implemented, oxygen deficiency in the piezoelectric body 120 is formed at an interface to form internal bias field. Due to the internal bias field, the piezoelectric body 120 is formed to have preferred polarization directions during the deposition of the piezoelectric body 120, thereby generating the self polarization. Therefore, the inertial sensor 100 according to the preferred embodiment of the present invention may omit the poling process upon manufacturing the piezoelectric body 120.

In addition, even though the poling process is performed, the thickness of the piezoelectric body 120 may be thinly implemented, thereby lowering the poling voltage. Therefore, after the integrated circuit is connected with the inertial sensor 100, even though the poling process is performed, it is possible to prevent the internal elements of the integrated circuit from being broken due to the poling voltage. In addition, even after the integrated circuit is connected with the inertial sensor 100, the poling process may be periodically performed as needed.

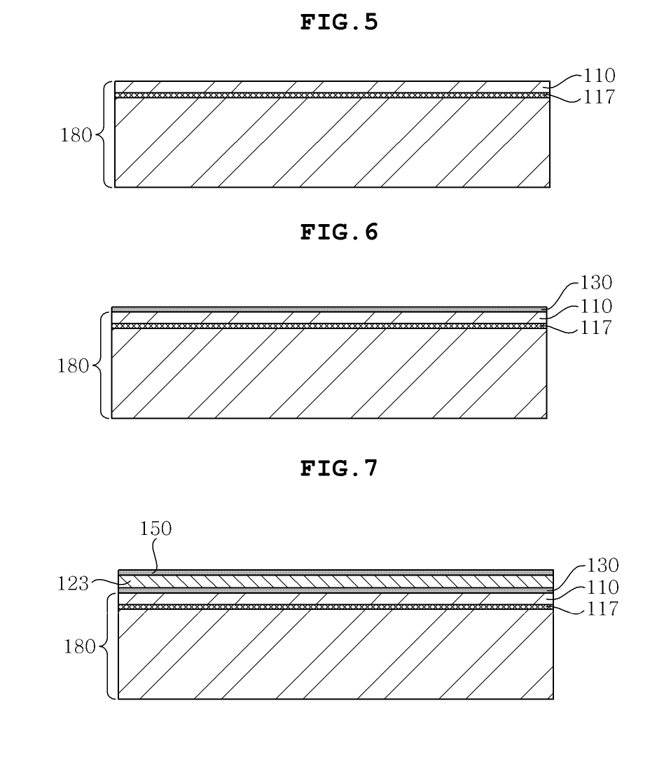

FIGS. 5 to 14 are cross-sectional views and plan views showing a process sequence of a method of manufacturing an inertial sensor according to a preferred embodiment of the present invention, wherein the cross-sectional views show the inertial sensor take along line A-A′, B-B′, C-C′, or D-D′ of the plan views.

As shown in FIGS. 5 to 14, the inertial sensor 100 according to the preferred embodiment of the present invention may include (A) forming the first electrode 130 on the membrane 110, (B) forming the piezoelectric body 120 on the first electrode 130 in a multilayer and forming the third electrode 150 between the layers of the piezoelectric body 120 formed in a multilayer, and (C) forming the second electrode 140 on the exposed surface of the piezoelectric body 120.

First, as shown FIG. 5, a process of preparing the membrane 110 is performed. Here, the membrane 110 is a portion of a base substrate 180 such as the SOI substrate, or the like. However, before the mass body 190 and the posts 195s are formed by selectively etching the base substrate 180, the membrane 110 is definitively differentiated, but means the top portion (in the case of the SOI substrate, the top portion of the silicon oxide film 117) of the base substrate 180.

Next, as shown in FIG. 6, a process of forming the first electrode 130 on the membrane 110 is performed. Here, the first electrode 130 may be formed by depositing titanium (Ti), platinum (Pt), or a combination thereof, or the like. In addition, the first electrode 130 is formed over the membrane 110 so as to be used as the common electrode.

Next, a process of forming the piezoelectric body 120 formed in a multilayer on the first electrode 130 and forming the third electrode 150 between the layers of the piezoelectric body 120 formed in a multilayer is performed.

In detail, as shown in FIG. 7, the first piezoelectric body 123 of one layer is formed on the first electrode 130 and the third electrode 150 is formed on the first piezoelectric body 123. In this case, the first piezoelectric body 123 may be formed by depositing lead zirconate titanate (PZT), barium titanate (BaTiO₃), lead titanate (PbTiO₃), lithium niobate (LiNbO₃), silicon dioxide (SiO₂), or the like. In addition, the third electrode 150 may be formed by depositing titanium (Ti), platinum (Pt), or a combination thereof, or the like.

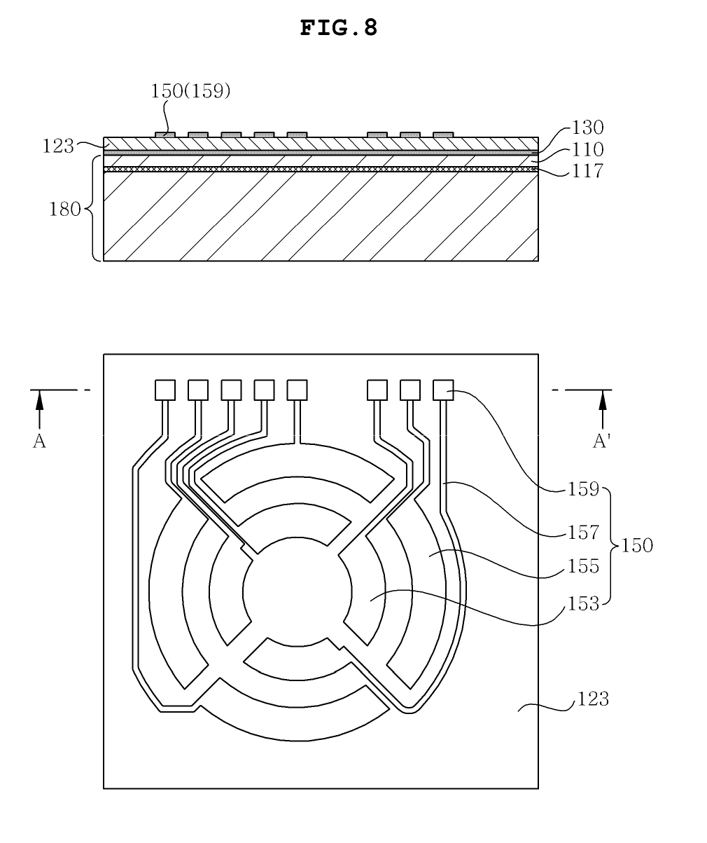

Next, as shown FIG. 8, a process of patterning the third electrode 150 is performed. Here, the third electrode 150 may be patterned through the selective etching. In addition, the third electrode 150 may be patterned to include the driving electrodes 153, the sensing electrodes 155, the wirings 157 connected with the driving electrodes 153 and the sensing electrodes 155, and the first pads 159 connected with ends of the wirings 157 (see a plan view of FIG. 8).

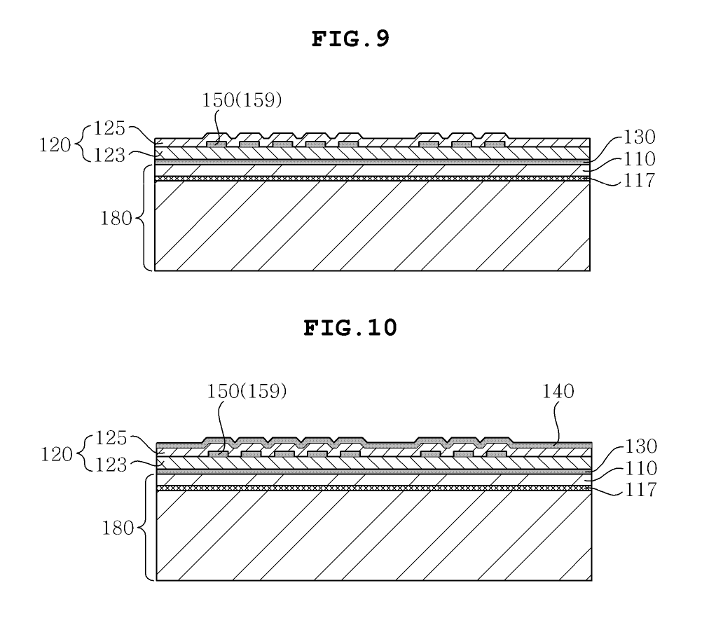

Next, as shown in FIG. 9, a process of forming the second piezoelectric body 125 of one layer on the first piezoelectric body 123 is performed. Here, the second piezoelectric body 125 may be formed by being deposited similar to the first piezoelectric body 123. Further, when the second piezoelectric body 125 is formed on the first piezoelectric body 123, the third electrode 150 is covered with the second piezoelectric body 125 and the third electrode 150 is disposed between the layers of the piezoelectric body 120.

Next, as shown in FIG. 10, a process of forming the second electrode 140 on the second electrode 140 is performed. Here, the second electrode 140 may be formed by depositing titanium (Ti), platinum (Pt), or a combination thereof, or the like, similar to the first electrode 130. In addition, the second electrode 140 is formed over the membrane 110 so as to be used as the common electrode.

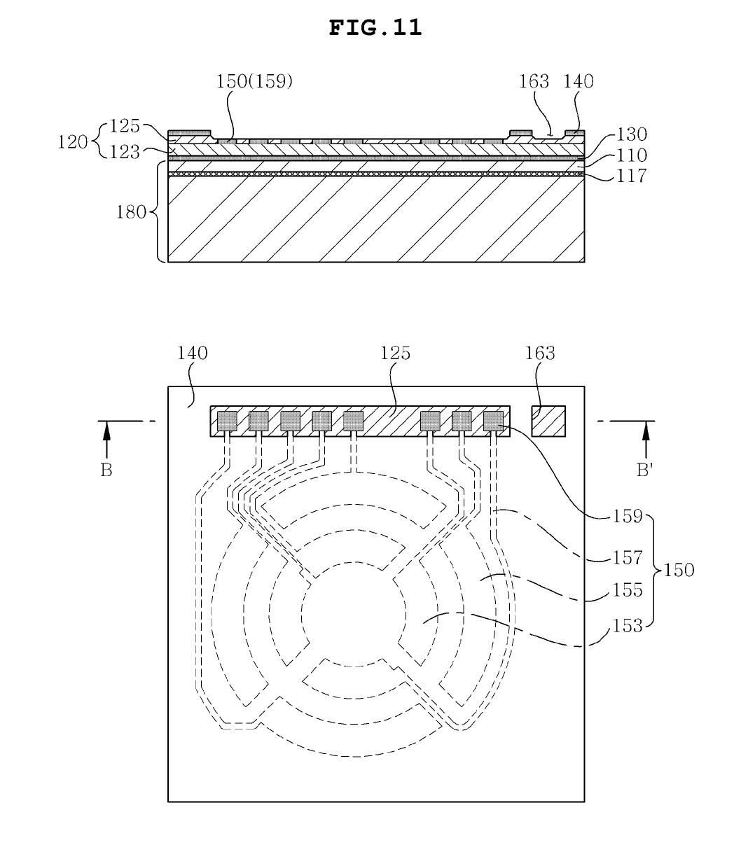

Next, as shown in FIG. 11, a process of exposing the first pads 159 by selectively removing the piezoelectric body 120 and the second electrode 140 is performed. Here, the first pads 159 are finally connected with the integrated circuit and therefore, the first pads 159 are exposed by selectively removing the piezoelectric body 120 and the second electrodes 140. In detail, the third electrode 150 is formed on the first piezoelectric body 123 and therefore, may be exposed by removing the second electrode 140 and the second piezoelectric body 125. However, only the first pads 159 needs to be exposed by selectively removing only the second electrode 140 corresponding to the first pads 159 and the second piezoelectric body 125 and in order to implement the advantages of the piezoelectric body 120 formed in a multilayer, the second electrodes 140 and the second piezoelectric body 125 corresponding to the sensing electrodes 155 and the driving electrodes 153 are not removed. Meanwhile, the first pads 159 may be exposed by removing the second electrode 140 and the second piezoelectric body 125 by the selective etching. Therefore, when the first pads 159 are exposed by removing the second electrode 140 and the second piezoelectric body 125 by the selective etching, a portion of a via hole 163 may be formed by the etching.

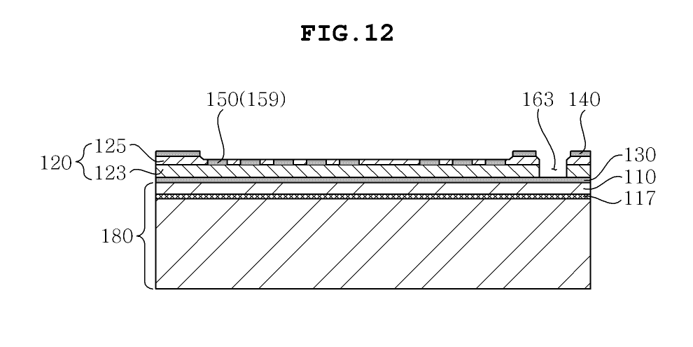

Next, as shown in FIG. 12, a process of forming the via hole 163 penetrating through the piezoelectric body 120 is performed. At the above-mentioned processes, a portion of the via hole 163 is formed by removing the second piezoelectric body 125 and therefore, at the present process, the via hole 163 completely penetrating through the piezoelectric body 120 is formed by removing the first piezoelectric body 123.

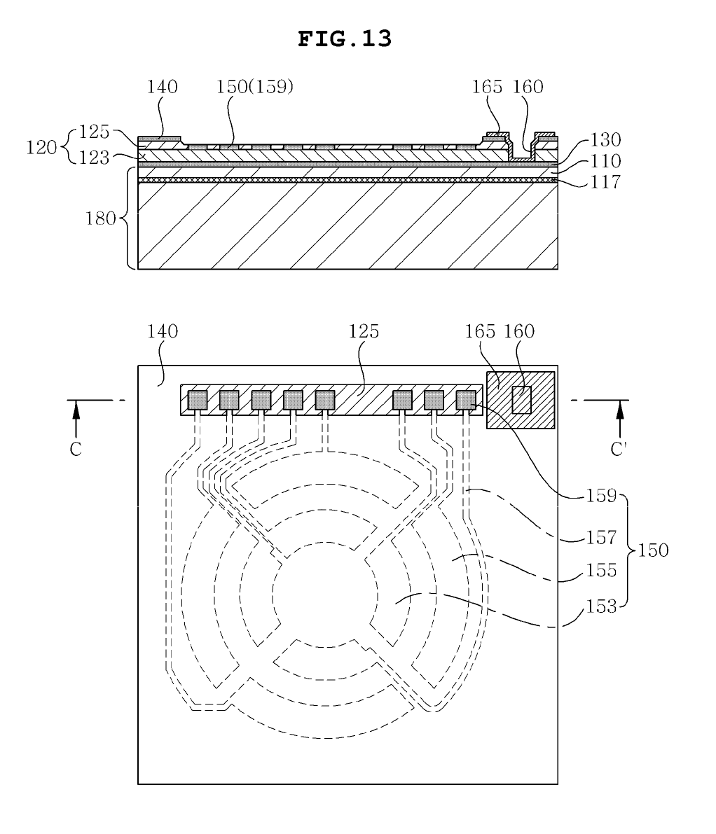

Next, as shown in FIG. 13, a process of forming the via 160 connecting the first electrode 130 with the second electrode 140 and the second pad 165 connected with the via 160 is performed. Here, the via 160 is formed in an inner wall of the via hole 163 to connect the first electrode 130 with the second electrode 140 and the second pads 165 is formed on the second electrode 140 so as to extend from the via 160, such that the second pad 165 may be connected with the control unit such as the integrated circuit, or the like. In this case, the via 160 and the second pad 165 may be integrally formed by depositing gold (Au), or the like.

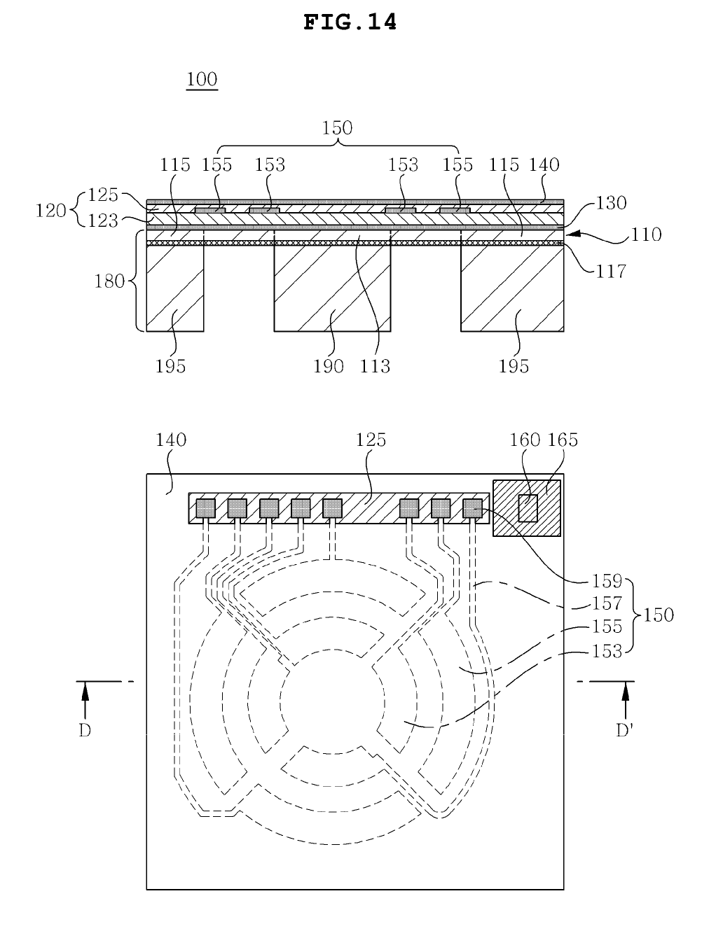

Next, as shown in FIG. 14, a process of forming the mass body 190 and the posts 195 by selectively etching the base substrate 180 such as the SOI substrate, or the like, is performed. In detail, when selectively etching the bottom portion of the base substrate 180 (in the case of the SOI substrate, the bottom portion of the silicon oxide film 117), the mass body 190 is disposed under the central portion 113 of the membrane 110 and the posts 195 are disposed under the edges 115 of the membrane 110.

However, the process of forming the mass body 190 and the posts 195 does not need to be necessarily performed after forming the first, second, third electrodes 130, 140, and 150 and the piezoelectric body 120, but may be performed before forming the first, second, and third electrodes 130, 140, and 150 and the piezoelectric body 120.

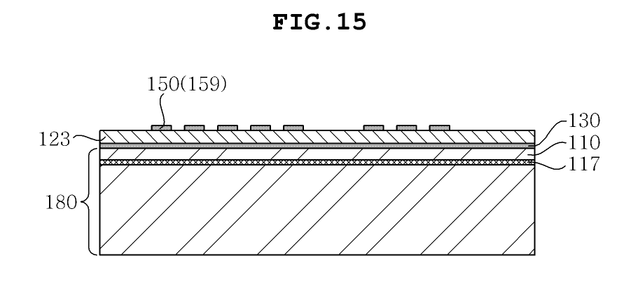

FIGS. 15 to 23 are cross-sectional views and plan views showing a process sequence of a method of manufacturing an inertial sensor according to another preferred embodiment of the present invention, wherein the cross-sectional views show the inertial sensor take along line E-E′, F-F′, G-G′, or H-H′ of the plan views.

As shown in FIGS. 15 to 23, the inertial sensor 200 according to the preferred embodiment of the present invention further includes a passivation layer 175 and a surface treatment layer 170 when comparing with the inertial sensor 100 according to the above-mentioned preferred embodiment of the present invention. Therefore, the preferred embodiment of the present invention is described based on the passivation layer 175 and the surface treatment layer 170 and the overlapping contents as the above-mentioned preferred embodiments of the present invention will be omitted.

First, as shown in FIG. 15, after the first electrode 130, a process of forming the first piezoelectric body 123, and the third electrode 150 on the membrane 110 in order and then, patterning the third electrode 150 is performed. The present process is the same as the above-mentioned preferred embodiment of the present invention and therefore, the related contents thereof will be described with reference to FIGS. 5 to 8.

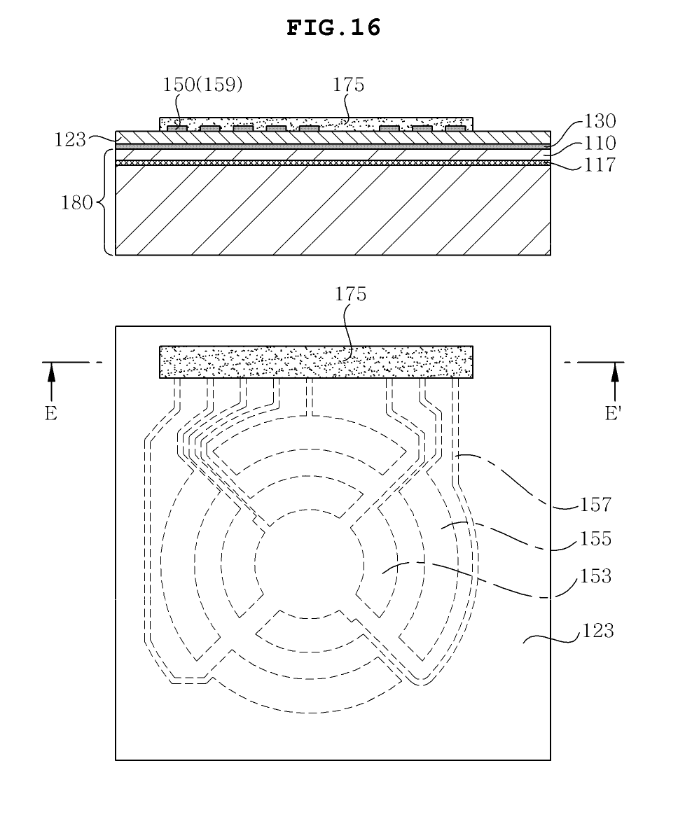

Next, as shown in FIG. 16, a process of forming the passivation layer 175 so as to protect the first pads 159 is performed. Herein, the passivation layer 175 serves to protect the first pads 159 during the manufacturing process. In detail, as described to be below, the first pads 159 are formed with the second piezoelectric body 125 and the second electrode 140 and then, the second piezoelectric body 125 and the second electrode 140 are removed by the selective etching. Therefore, the passivation layer 175 is formed so as to prevent the first pads 159 from being damaged during the process.

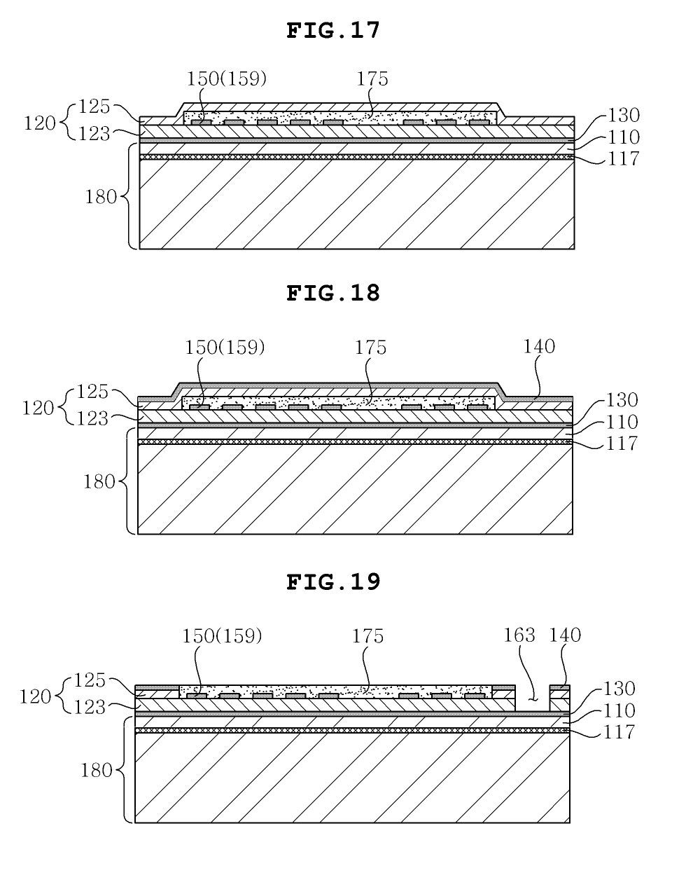

Next, as shown in FIG. 17, a process of forming the second piezoelectric body 125 of one layer on the first piezoelectric body 123 is performed. As described above, when the second piezoelectric body 125 is formed on the first piezoelectric body 123, the third electrode 150 is covered with the second piezoelectric body 125 and the third electrode 150 is disposed between the layers of the piezoelectric body 120. However, the first pads 159 are protected with the passivation layer 175 such that the first pads 159 do not directly contact the second piezoelectric body 125.

Next, a process of forming the second electrode 140 is formed on the second piezoelectric body 125 as shown in FIG. 18, and then, selectively removing the piezoelectric body 120 and the second electrode 140 to expose the first pads 159, as shown in FIG. 19 is performed. Here, the second electrode 140 and the second piezoelectric body 125 may be removed by the selective etching. However, the first pads 159 are covered with the passivation layer 175 and therefore, the damage of the first pads 159 can be prevented even though the second electrode 140 and the second piezoelectric body 125 are removed by the selective etching. Meanwhile, at the present process, when the first pads 159 are exposed by removing the second electrode 140 and the second piezoelectric body 125 by the selective etching, the via hole 163 may also be formed by the etching.

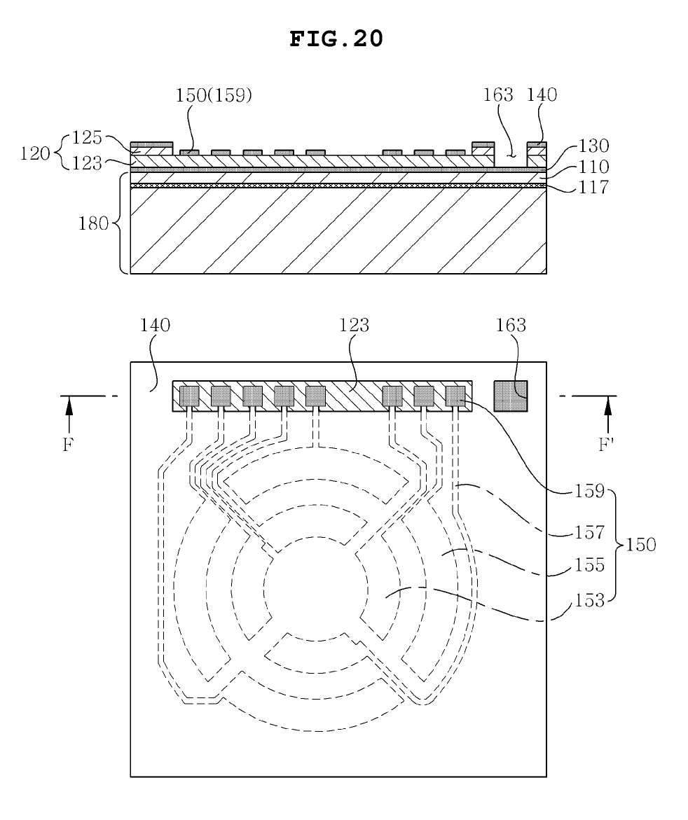

Next, as shown FIG. 20, a process of removing the passivation layer 175 is performed. As described above, the passivation layer 175 completes the role of protecting the first pads 159 during the manufacturing process and therefore, the passivation layer 175 is removed at the present process.

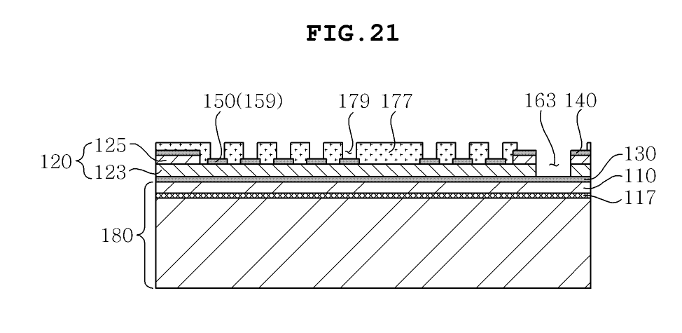

Next, a shown in FIG. 21, a process of applying a photoresist 177 and then, selectively patterning the photoresist 177 is performed. Here, the photoresist 177 is patterned to have opening parts 179 corresponding to the surface treatment layer 170 of the first pads 159, the via 160, and the second pads 165 that are formed at a process to be described below. In this case, the photoresist 177 may be patterned through an exposing/developing process.

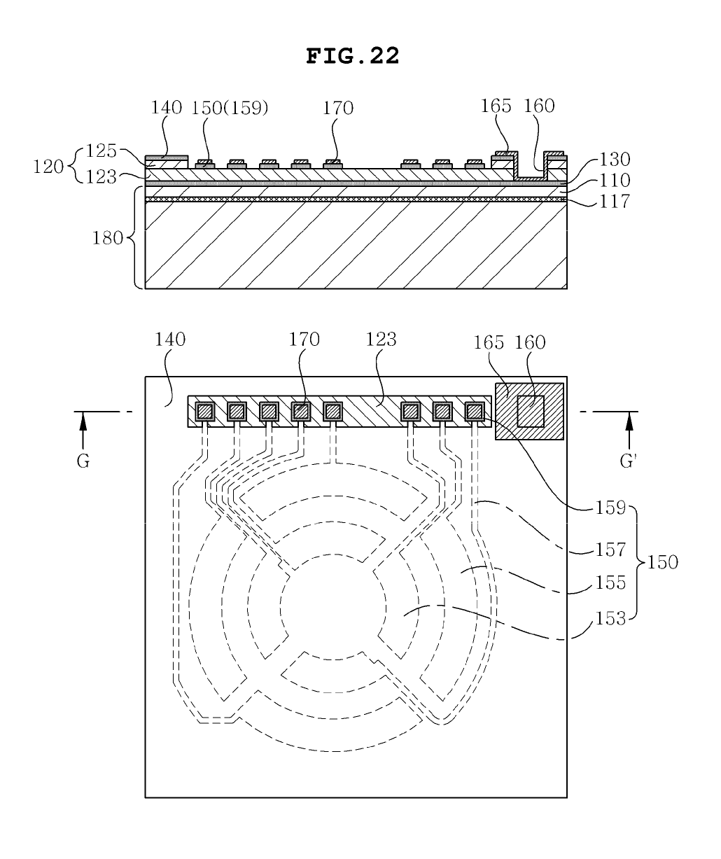

Next, as shown in FIG. 22, a process of forming the surface treatment layer 170 on the first pads 159, the via 160 connecting the first electrode 130 with the second electrode 140, and the second pads 165 connected with the via 160 is performed. Here, the surface treatment layer 170 is formed on the exposed surface of the first pads 159 to prevent the first pads 159 from being oxidized and to ensure the high electric conductivity. In addition, the via 160 is formed in an inner wall of the via hole 163 to connect the first electrode 130 with the second electrode 140. In addition, the second pad 165 is formed on the second electrode 140 to extend from the via 160 so as to be connected with the control unit such as the integrated circuit, or the like. Meanwhile, the surface treatment layer 170, the via 160, and the second pad 165 may be integrally formed by depositing gold (Au), or the like.

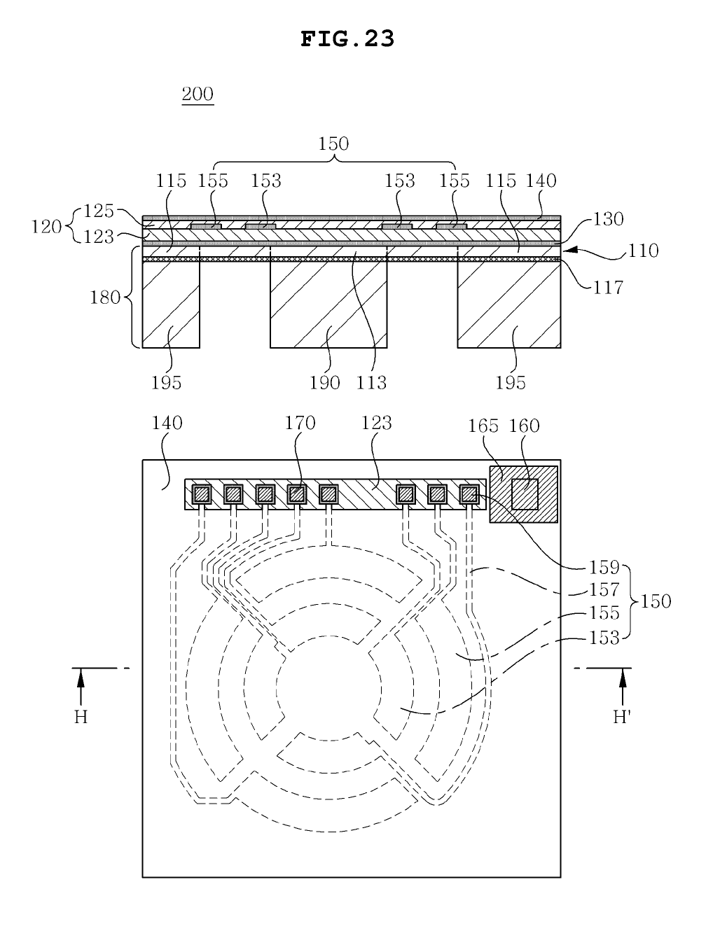

Next, as shown in FIG. 23, a process of forming the mass body 190 and the posts 195 by selectively etching the base substrate 180 such as the SOI substrate, or the like, is performed. In detail, when selectively etching the bottom portion of the base substrate 180 (in the case of the SOI substrate, the bottom portion of the silicon oxide film 117), the mass body 190 is disposed under the central portion 113 of the membrane 110 and the posts 195 are disposed under the edges of the membrane 110.

Meanwhile, the inertial sensors 100 and 200 according to the preferred embodiments of the present invention describe the case in which the piezoelectric body 120 is formed in two layers, which is only an example. The scope of the invention prevention includes the piezoelectric body 120 formed in a multilayer of two or more layers.

The preferred embodiments of the present invention can drive the mass body like the prior art even though the relatively lower voltage is applied to the piezoelectric body, by forming the piezoelectric body in the multilayer. Further, the preferred embodiments of the present invention can largely drive the mass body as compared with the prior art, when the same voltage as the prior art is applied.

In addition, the preferred embodiments of the present invention can form the piezoelectric body in the multilayer to output the relatively higher voltage when the displacement of the mass body is sensed, by forming the piezoelectric body in the multilayer, thereby increasing the sensitivity of the inertial sensor.

Moreover, the preferred embodiments of the present invention can form the piezoelectric body in the multilayer to make the thickness of the piezoelectric body thinner, thereby implementing the self polarization.

Also, the preferred embodiments of the present invention can form the piezoelectric body in the multilayer to make the thickness of the piezoelectric body thinner, thereby lowering the poling voltage. As a result, even though the poling voltage is performed after the integrated circuit is connected with the inertial sensor, it is possible to prevent the internal elements of the integrated circuit from being broken due to the poling voltage.

Although the preferred embodiments of the present invention have been disclosed for illustrative purposes, they are for specifically explaining the present invention and thus an inertial sensor and a method of manufacturing the same according to the present invention are not limited thereto, but those skilled in the art will appreciate that various modifications, additions and substitutions are possible, without departing from the scope and spirit of the invention as disclosed in the accompanying claims. Accordingly, any and all modifications, variations or equivalent arrangements should be considered to be within the scope of the invention, and the detailed scope of the invention will be disclosed by the accompanying claims.

What is claimed is:

1. An inertial sensor, comprising:
a membrane;
a piezoelectric body formed in a multilayer above the membrane;
a first electrode formed between the membrane and the piezoelectric body;
a second electrode formed on an exposed surface of the piezoelectric body; and
a third electrode formed between layers of the piezoelectric body formed in a multilayer.

2. The inertial sensor as set forth in claim 1, wherein the third electrode includes first pads.

3. The inertial sensor as set forth in claim 2, wherein the first pads are exposed from the piezoelectric body and the second electrode.

4. The inertial sensor as set forth in claim 1, further comprising:
a via connecting the first electrode with the second electrode by penetrating through the piezoelectric body; and
a second pad connected with the via.

5. The inertial sensor as set forth in claim 1, wherein the first electrode is a common electrode formed over the membrane and the second electrode is a common electrode formed over the piezoelectric body.

6. The inertial sensor as set forth in claim 1, wherein the first electrode and the second electrode are grounded.

7. The inertial sensor as set forth in claim 1, wherein the third electrode is patterned.

8. The inertial sensor as set forth in claim 7, wherein the third electrode includes:
driving electrodes;
sensing electrodes;
wirings connected with the driving electrodes and the sensing electrodes; and
first pads connected with ends of the wirings.

9. The inertial sensor as set forth in claim 2, further comprising a surface treatment layer formed on the first pads.

10. The inertial sensor as set forth in claim 1, further comprising:
a mass body disposed under a central portion of the membrane; and
posts disposed under edges of the membrane.

11. A method of manufacturing an inertial sensor, comprising:
(A) forming a first electrode on a membrane;
(B) forming a piezoelectric body on the first electrode in a multilayer and forming a third electrode between layers of the piezoelectric body formed in a multilayer; and
(C) forming a second electrode on an exposed surface of the piezoelectric body.

12. The method as set forth in claim 11, wherein at step (B), the third electrode further includes first pads.

13. The method as set forth in claim 12, further comprising exposing the first pads by selectively removing the piezoelectric body and the second electrode after step (C).

14. The method as set forth in claim 11, further comprising forming a via connecting the first electrode with the second electrode by penetrating through the piezoelectric body and second pads connected with the via after step (C).

15. The method as set forth in claim 11, wherein at step (A), the first electrode is a common electrode formed over the membrane and
at step (C), the second electrode is a common electrode formed over the piezoelectric body.

16. The method as set forth in claim 11, wherein at step (B), the third electrode is patterned.

17. The method as set forth in claim 16, wherein the third electrode includes:
driving electrodes;
sensing electrodes;
wirings connected with the driving electrodes and the sensing electrodes; and
first pads connected with ends of the wirings.

18. The method as set forth in claim 12, wherein at step (B), a passivation layer is formed so as to protect the first pads after the third electrode is formed, and
the passivation layer is removed after step (C).

19. The method as set forth in claim 12, further comprising forming a surface treatment layer on the first pads after step (C).

20. The method as set forth in claim 11, wherein the inertial sensor further include:
a mass body disposed under a central portion of the membrane; and
posts disposed under edges of the membrane.
